(19) United States
(12) Patent Application Publication
(10) Pub. No.: US 2009/0294893 A1
(43) Pub. Date: Dec. 3, 2009

(54) ISOLATION TRENCH INTERSECTION STRUCTURE WITH REDUCED GAP WIDTH

(75) Inventors: Ralf Lerner, Erfurt (DE); Uwe Eckholdt, Hohenfelden (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: X-FAB SEMICONDUCTOR FOUNDRIES AG, Erfurt (DE)

(21) Appl. No.: 12/096,580

(22) PCT Filed: Dec. 8, 2006
(86) PCT No.: PCT/EP06/69498

§ 371 Date: Oct. 20, 2008

(30) Foreign Application Priority Data
Dec. 10, 2005 (DE) 10 2005 059 034.9

(51) Int. Cl. H01L 29/06

(52) U.S. Cl. 257/506; 257/E29.02

(57) ABSTRACT

The invention relates to isolation trenches having a high aspect ratio for trench-insulated smart power technologies in Silicon On Insulator (SOI) silicon wafers. The specific geometric layout of the intersections and junctions of the isolation trenches allows error rate reduction and simplification of manufacture.

### CROSS REFERENCE TO RELATED APPLICATIONS

This application is a U.S. National Stage Application of International Application No. PCT/EP2006/069498, filed Dec. 8, 2006, which claims the benefit of German Patent Application No. DE 10 2005 059 034.9, filed on Dec. 10, 2005, the disclosure of which is herein incorporated by reference in its entirety. PCT/EP2006/069498 designated the United States and was published in English.

### FIELD OF THE DISCLOSURE

The present invention relates to semiconductor device assemblies formed on a substrate, such as on a silicon wafer and in particular on an SOI wafer, wherein semiconductor regions are defined in a semiconductor layer by isolation trenches.

### BACKGROUND OF THE DISCLOSURE

In SOI silicon wafers isolation trenches are used to insulate different devices (for instance transistors) or entire regions of different potential from each other in integrated circuits, such as smart power integrated circuits. The isolation trench may in this case surround, for instance, the device or the region to be isolated in a circular manner, as is for instance described in U.S. Pat. No. 5,734,192 or also in U.S. Pat. No. 6,394,638. Moreover, in U.S. Pat. No. 5,283,461 a trench structure is disclosed in which the devices to be isolated are separated by a network of isolation trenches, thereby creating, as is shown in FIG. 1a, intersections (cf. FIG. 1a) and T-shaped connections, i.e., junctions (FIG. 1b), of the isolation trenches.

FIG. 1a and FIG. 1b illustrate a top view of an active silicon layer, in which an isolation trench A is formed with a width or breadth 14 such that the isolation trench A is bordered on both sides by a region of the active silicon layer 12, 12′ of the wafer. At the intersections or junctions a diagonal width 16 of the isolation trenches A is created. The diagonal width 16 at the intersection is significantly greater than the width 14 of the individual, linearly extending isolation trench A. In the illustrative example shown, the width 16 is approximately 1.4 times the width 14.

In U.S. Pat. No. 6,524,928 the structure of an isolation trench A is described in an illustrative manner. FIG. 2 of this document schematically illustrates a sectional view of the isolation trench in an SOI substrate, wherein a corresponding structure may also be used for the present invention. The base material is the SOI wafer consisting of a carrier wafer, i.e. the substrate 20, the active silicon layer 13 and a buried oxide 22, which separates the carrier wafer 20 from the silicon layer 13 used for active devices. First, an insulation layer 24, for instance a dielectric material such as silicon dioxide, is formed on the sidewalls of the etched isolation trench A. Thereafter, the isolation trench is filled with a fill material 26, for instance polysilicon, and the trench is planarized. The trench A separates the two regions 12, 12′ resulting from the active silicon layer 13.

The deposition of the fill layer 26 for filling the isolation trench is accomplished, for instance, by chemical or physical deposition techniques (CVD or PVD processes). Since the isolation trench is covered from both trench sides during the deposition of the fill layer, theoretically a layer thickness of at least half of the width 14 is required so as to fill the linear isolation trench having no intersections. However, for a complete filling of the entire isolation trench system this is not sufficient, since also the intersection area and thus the width 16 is to be taken into consideration for the complete filling. The layer thickness required therefor thus amounts to at least half of the width 16 and is thus significantly greater than the layer thickness that would be required for filling the trench width 14. An increased layer thickness, however, means increased process times and increased error rates and therefore also increased production costs.

U.S. Pat. No. 5,072,266 describes a power MOSFET wherein the dielectric strength of the gate is increased by enclosing the gate by means of an isolation trench, which is provided in the form of a polygon, such as a hexagon. With respect to the problems relating to an efficient filling of isolation trenches this document does not provide any hints.

### OBJECTS OF THE DISCLOSURE

It is an object of the present invention to provide an isolation trench structure and a design or a layout, respectively, in which filling is possible during the deposition of the fill layer for the trench with as low an effort as possible even at intersection and junction locations.

### SUMMARY OF THE INVENTION

To this end, according to the present invention a design for the isolation trench structure in semiconductor devices is provided. With the design, an adaptation of the resulting width may be achieved locally in areas of an intersection or a junction of isolation trenches. The resulting width is adapted such that during the deposition of insulating material and fill material, the maximum gap width (that is, the maximum distance to the semiconductor material that defines the edges of the isolation trench structure after the etch process) is less than in linear sections of the isolation structures outside the intersection and/or junction areas. In this manner, the aspect ratio of the isolation trench structure, i.e. the ratio of trench depth to trench width, is increased locally at the intersection and/or junction areas only, while nevertheless substantially maintaining the desired aspect ratio. Hence, an efficient filling of the isolation trench structure may be accomplished without requiring increased process times that are necessary in conventional techniques at intersection and/or junction areas due to the increased gap width.

### BRIEF DESCRIPTION OF THE DRAWINGS

FIG. 1a shows a top view of a conventional isolation trench structure of a semiconductor device assembly or a corresponding layout structure for forming a semiconductor device assembly having an intersection area;

FIG. 1b illustrates a top view of a conventional isolation trench structure of a semiconductor device assembly or a corresponding layout structure for forming a semiconductor device assembly having a junction area;

FIG. 2 illustrates a cross-sectional view of an isolation trench that extends to a buried insulating layer in an SOI configuration;

FIG. 3 illustrates a top view of a 90 degree intersection of isolation trenches corresponding to an example of the invention, in a schematic view;

FIG. 3a illustrates a top view of a junction including a middle island;

FIG. 4 illustrates a further variant as in FIG. 3, however without a middle island but with isolation trenches narrowing in the intersection area;

FIG. 4a illustrates a junction having a narrowing isolation trench;

FIG. 5 illustrates a 90 degree corner of an isolation trench having a contraction.

### DETAILED DESCRIPTION OF THE DISCLOSURE

The following description is intended to convey a thorough understanding of the embodiments described by providing a number of specific embodiments and details involving an isolation trench intersection structure with reduced gap width. It should be appreciated, however, that the present invention is not limited to these specific embodiments and details, which are exemplary only. It is further understood that one possessing ordinary skill in the art, in light of known systems and methods, would appreciate the use of the invention for its intended purposes and benefits in any number of alternative embodiments, depending on specific design and other needs.

An isolation trench structure and thus a layout is proposed that has a minimal possible width in order to allow filling of the trench even at a low layer thickness with a reduced deposition time and with a low error rate at reduced production costs. Furthermore, for a stable etch process of the trench, a certain aspect ratio may be maintained outside the intersection and/or junction areas so as to maintain a minimum width of the trench for a given thickness of the active silicon layer.

The local reduction of the width of the isolation trenches at the intersection and/or junction areas may be adapted to the corresponding process and device requirements such that the gap dimensions (i.e. the effective trench width within the areas of reduced dimensions) still meet the requirements with respect to the insulation, etch and gap fill behavior. Further, the substantial sections of the isolation trenches (the linear sections outside of the intersection and/or junction areas) having the increased total width result in a very reliable functional and structural behavior with reduced process times.

In some embodiments, an isolation trench structure is provided in a semiconductor device assembly. The isolation trench structure comprises isolation trenches that form an intersection area and/or a junction area and define regions of semiconductor material, which regions are electrically insulated from each other by the isolation trenches. Furthermore, a spacing between two semiconductor regions that are separated by the isolation trenches may be reduced in the intersection area and/or junction area.

A reduction of the spacing within the intersection area and/or junction area between two semiconductor regions separated by a trench compared to the spacing between two separated semiconductor regions outside of the intersection area and/or junction area, i.e. the trench width, provides for the advantages described above.

The local reduction of the gap width to be filled during the fill process may be accomplished in one embodiment by providing overhangs of the semiconductor material within the intersection and/or junction areas. In other embodiments a middle island of semiconductor material is maintained in this area during the patterning. Hence, contrary to conventional layout patterns, according to embodiments of the present invention, the intersection areas and/or the junction areas are designed such that on the one hand, the minimum requirements with respect to dielectric strength and etch behavior may be met, while on the other hand, the filling may be achieved in a reliable manner at a reduced process time.

In this context, a middle island of semiconductor material is to be understood such that in the corresponding layout measures may be taken in the intersection and/or junction area, which result, during the actual patterning process (i.e. during the formation of an etch mask and the actual etch process) in the maintaining of material of the initial semiconductor layer locally in the intersection and/or junction areas during the etch process, wherein the maintained material may be surrounded at all sidewall areas by a gap or a trench according to a top view of the semiconductor layer. In this case, the term ‘middle island’ in the same manner as the term ‘isolation trench’ will describe the device structure after the fill process, in which respective gaps or trench sections are filled with an appropriate fill material so that the middle island represents semiconductor material that, in a top view, is surrounded laterally by fill material after performing a planarization step.

In some embodiments the semiconductor layer may be provided as a material layer on a buried insulating layer such that an SOI architecture is obtained, wherein the isolation trenches may extend at least to the buried insulating layer. In this manner, the semiconductor regions defined by the isolation trenches may be electrically completely insulated from each other so that very different potentials may be used during operation. For example, voltages as may occur for power applications (for instance in the range of approximately 50 volts and significantly higher, such as 100 volts-600 volts and higher) may be processed together with small signal voltages in a reliable manner within the semiconductor regions separated by the corresponding isolation trenches. In this configuration also the middle island may be galvanically separated from the remaining semiconductor regions and thus forms a potential-free “island”, i.e. an island that is not contacted by the surrounding regions to be insulated.

In a further aspect, an isolation trench structure may be provided at least in an intersection area of isolation trenches of semiconductor device assemblies, wherein regions having a different potential during operation may be electrically insulated from each other by the isolation trenches. In the center of the intersection of the isolation trenches, a middle island may be provided that is comprised of the same material as the regions, wherein the middle island may be configured in shape, size and position such that the size of the intersection area may be reduced so that a junction of reduced width compared to the width of the isolation trench may be obtained from one isolation trench to the other.

Hence, the effective gap width in the center of the intersection may be significantly reduced so that the previously described advantages may be obtained during the fill process.

In an exemplary embodiment, the middle island has a quadratic shape and exhibits with respect to its linear edges a 45 degree rotation with respect to a length direction of trench edges of at least one isolation trench.

In this manner, in particular for 90 degree intersections, a simple geometric structure of the trench layout may be obtained, wherein additionally areas with sharp edges of the semiconductor regions encounter a linear opposite edge of the semiconductor island, so that the patterning process and the fill process proceed in a reliable manner.

In some embodiments a middle island may be provided also in a junction area of isolation trenches, such that any appropriate structure of isolation trenches may be realized as a network, wherein the advantages of the enhanced fill characteristics may be maintained.

In a similar manner, a junction of reduced gap width may be provided in some embodiments, which is accomplished by appropriately formed material overhangs.

In some embodiments the various patterning measures for enhancing the fill characteristics may be combined so that a wide variety is accomplished during the adaptation of characteristics of the corresponding intersection and/or junction areas, for example with respect to the insulation behavior, the etch behavior or the fill behavior.

Additionally, in some embodiments the concept of the present invention may be applied to corner areas of isolation trenches without a junction or an intersection.

Within the scope of the present invention, the inventive solution may also be applied to intersections and junctions having angles other than 90 degrees.

Illustrative embodiments will now be described with reference to the drawings. In the drawings, identical or similar components are denoted by the same reference signs.

With reference to the drawings, illustrative embodiments will be described wherein it should be appreciated that the Figures are to be understood as schematic illustrations of actual semiconductor device assemblies as well as appropriate layout structures for forming the same. Hence, in real semiconductor device assemblies, process induced deviations with respect to the forms shown in the Figures and thus deviations from the actual layouts may occur. For example, in actual devices the edges and corners shown may be rounded to a certain degree.

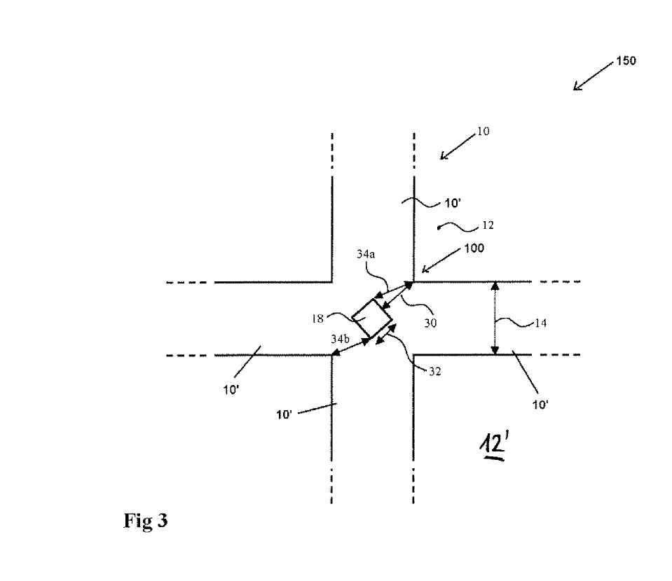

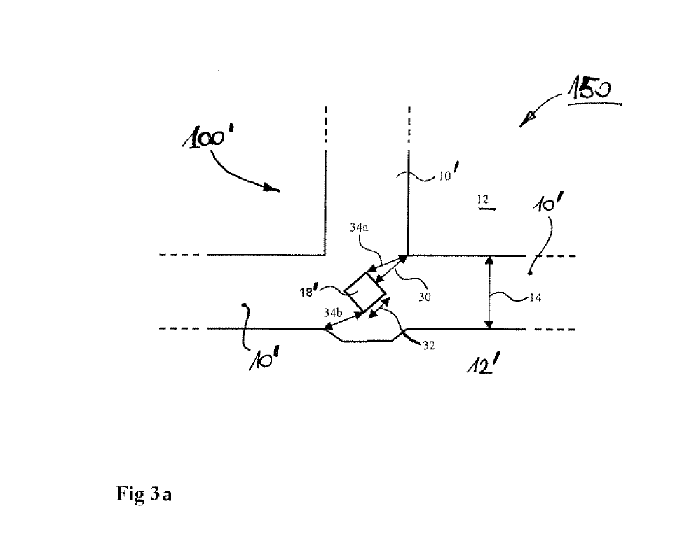

FIG. 3 illustrates a portion of a device assembly 150 or of a layout therefrom, respectively. The isolation trenches 10, 10′ define the regions 12 of semiconductor material that in one embodiment is a silicon material, wherein also other materials may be used, as is required for the desired device characteristics. Respective two regions 12, 12′ may be separated by the isolation trenches 10′ such that a gap between the separated semiconductor regions may be created that may be refilled subsequently with an appropriate fill material, as is already described above. In the embodiment shown, four linear sections 10′ having a trench width 14 form an intersection area 100.

A reduction of an increase of width of the isolation trench, i.e., of the effective gap width in the intersection point or intersection area 100 may be achieved by maintaining a middle island 18 consisting of semiconductor material corresponding to the regions 12, for instance in the form of a silicon material 13, in the middle of the intersection area 100 so as to have an edge length 32, as is shown. In this manner, the width of the isolation trenches to be filled, i.e., the effective gap width, may be reduced to the width 30 and hence respective thinner (vertical) layers may be used for filling the trenches 10′, which have the desired design width 14 outside the intersection area 100.

In the embodiment shown, by arranging the middle island 18 so as to be rotated by 45 degrees with respect to the actual trench progression, the greatest width 34a of isolation trenches to be filled may be reduced in the intersection area 100 and amounts to about the value of the spacing 30 between the corner of one of the regions 12 and the edge (the flank) of the middle island 18. The diagonal gap width or breadth to be filled in the intersection point or intersection area 100 is in one embodiment reduced by arranging the middle island 18 such that the sum of the diagonal spacings 34a, 34b approximately corresponds to the value of the width 14 of the isolation trenches outside of the intersection area 100. In this case, however, the middle island 18 is not provided with an arbitrary size so as to maintain influences on the etch rate during the trench etching and during the fabrication of the trench isolation layer as low as possible or so as to prevent the influences.

By appropriately designing the edge length 32 of the middle island 18, the remaining maximum width 34a or 34b to be filled may correspond to half of the width 14 of the linear isolation trenches 10′. In this manner, the total structure 10 of the isolation trenches 10′ may be filled in a void-free manner on the basis of a minimal thickness of the deposited fill layer. A minimum thickness on the other hand may result in a minimum process time, reduced elastic stress and minimal production costs for the fill process.

FIG. 3a schematically illustrates a junction area 100′ of trenches 10′, in which a middle island 18′ is provided such that also a reduction of the effective gap width to be filled in the area 100′ is obtained.

Since the middle islands 18, 18′ may be provided as semiconductor materials without contacts, a sufficiently high dielectric strength may be achieved despite the reduction of the effective gap width in the intersection area, so that the regions 12 may have a great difference in potential during operation, as may be the case for instance in smart power applications. For example, the regions 12 and 12′ may have a difference in potential of several hundred volts and more. At the trench 10′ the voltage is generated in the form of a potential difference.

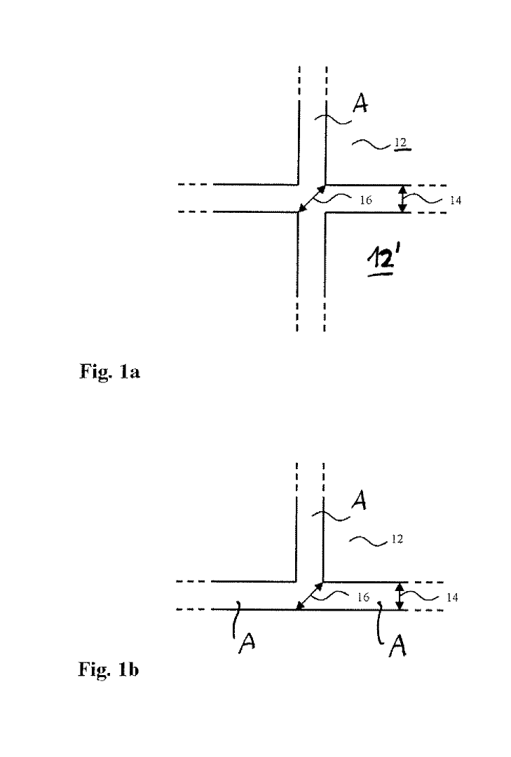

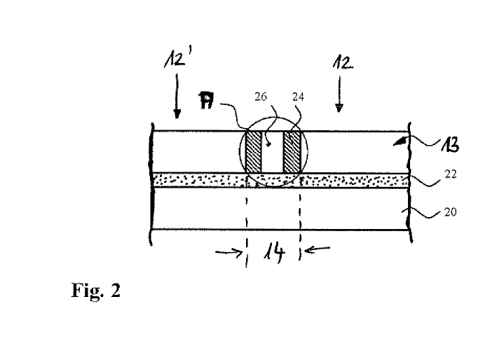

In one embodiment an SOI isolation trench structure is provided in the intersection and junction areas 100, 100′ of isolation trenches 10′ (layout) with a width 14 for and/or in semiconductor device assemblies 150. Regions 12 having a different potential are electrically insulated from each other by the isolation trenches 10′, wherein in the center of the intersection or junction 100, 100′ of the isolation trenches 10′ a middle island 18 or 18′, respectively, formed of the same material as the regions 12 is provided, however with a non-processed surface, wherein the island is provided with respect to shape, size and position such that the size of the intersection or junction area may be reduced, so that a transition from one isolation trench to the other may be obtained that may be reduced in width compared to the width of the isolation trenches. The gap width to be filled may be reduced compared to conventional intersections and junctions, as are shown in FIGS. 1a and 1b, due to the remaining semiconductor materials of the middle islands 18 or 18′, respectively.

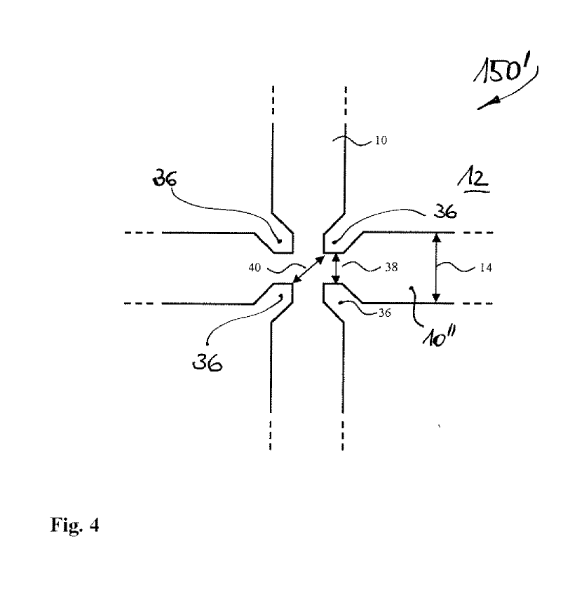

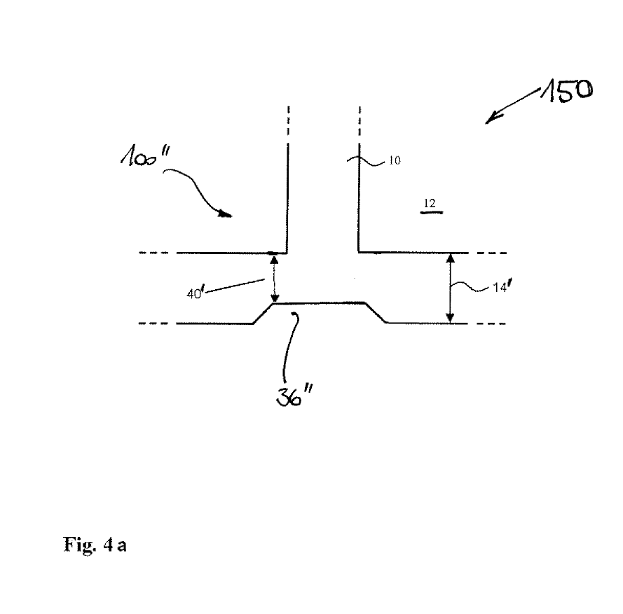

FIG. 4 illustrates an embodiment of the semiconductor device 150 for lower electrical voltages, for instance in the range of approximately 100V-200V or less. In this case, the portion illustrated may represent a large area portion with lower potential differences so that the neighboring regions 12 allow, at least locally, reduced insulation spacings wherein in other areas conditions may prevail as are described with reference to FIGS. 3 and 3a and hence correspondingly configured isolation trenches having middle islands 18, 18′ may be provided, or within the entire device 150 generally lower operating voltages are provided.

Due to the lower voltages the middle island in the intersection point or intersection area 100 may be omitted. The isolation trench 14 is reduced in the intersection area, at least in the center of the intersection area 100 or at the actual intersection point, with respect to its width. Substrate overhangs 56 are created, which reduce the width 14 of the isolation trench 10″ to the width 38. The diagonal width of the isolation trench may be reduced to the width 40. Based on an appropriate selection of dimensions, that is, for a width 40, which substantially corresponds to half of the width 14, the isolation trench structure may be filled with minimal layer thickness.

FIG. 4a illustrates a junction area 100″ of the device 150, wherein the effective gap width to be filled may be reduced to 40′ in the area of the overhang 36″. For example, the effective gap width 40′ may reach approximately half the trench width 14′ outside of the junction area 100″.

In one embodiment, an SOI isolation trench structure is provided in the intersection and junction areas 100, 100′ of isolation trenches (layout) of semiconductor device assemblies 150, which electrically insulate regions 12 having a different potential with respect to each other by the isolation trenches 10, wherein the width 14 of the isolation trenches 10 in the intersection and junction areas 100 and 100′, respectively, may be reduced by overhangs 36 of the active silicon layer 12.

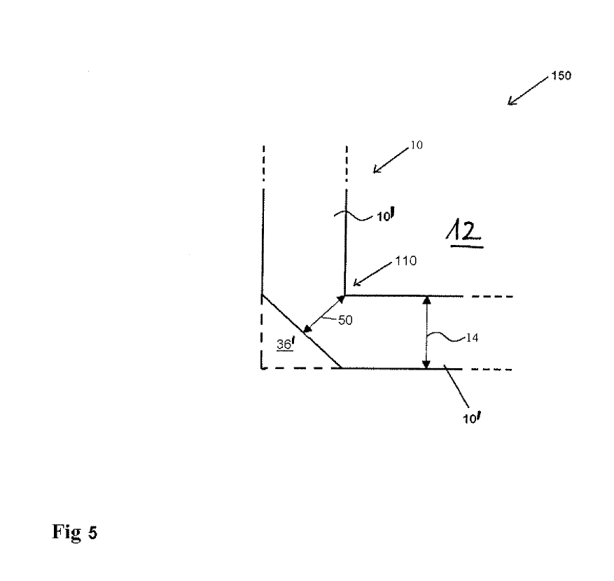

FIG. 5 illustrates a corner area 110 of the device 150, in which a material overhang 36′ allows a reduction of the effective width compared to a conventional corner as is illustrated in dashed lines. As shown, by flattening the outer edge a reduced gap width 50 is obtained, so that a very efficient improvement of the fill behavior is achieved.

The embodiments of the invention may therefore provide a trench isolation structure and a layout therefor, respectively, so as to efficiently improve the fill behavior as well as the thermal conditions, in particular in the area of intersections and/or junctions, by reducing the effective gap width or breadth of the isolation trenches in the intersection areas and/or junction areas compared to conventional structures.

By means of semiconductor material overhangs or semiconductor islands, the fill conditions may be adjusted in intersection and/or junction areas such that a void-free filling may be obtained at a reduced process time.

The embodiments described above may be combined in an appropriate manner such that a high degree of flexibility may be obtained for adjusting the trench characteristics (trenches and intersections and junctions in a given topology as a “structure”). For instance, in corresponding intersections or junctions of device areas, in which resulting potential differences are less than, for instance, 200V and less, the middle islands may be omitted and the isolation trenches may be reduced in width at the intersection and junction areas by other means, while in other cases the provision of the middle islands may result in the reduced gap width.

Accordingly, the embodiments of the present inventions are not to be limited in scope by the specific embodiments described herein. Further, although some of the embodiments of the present invention have been described herein in the context of a particular implementation in a particular environment for a particular purpose, those of ordinary skill in the art should recognize that its usefulness is not limited thereto and that the embodiments of the present inventions can be beneficially implemented in any number of environments for any number of purposes. Accordingly, the claims set forth below should be construed in view of the full breadth and spirit of the embodiments of the present inventions as disclosed herein. While the foregoing description includes many details and specificities, it is to be understood that these have been included for purposes of explanation only, and are not to be interpreted as limitations of the invention. Many modifications to the embodiments described above can be made without departing from the spirit and scope of the invention.

### TABLE OF REFERENCE SIGNS

10: isolation trenches
10′: isolation trench section outside of intersection and/or junction areas
13: active silicon layer and regions 12, 12′ formed therefrom
14: width of the individual isolation trench outside of the intersection and/or junction areas
14′: width of the individual isolation trench outside of the intersection and/or junction areas in device regions having a low voltage
16: diagonal width (gap width) of the isolation trench at the point of intersection of an intersection
18: middle island in an intersection area
18′: middle island in a junction area
20: carrier wafer/substrate
22: buried oxide
24: insulation layer
26: fill layer
30: diagonal width (gap width) of the isolation trench between the corner of the active silicon layer 12 and the middle island 18
32: edge length of the middle island 18 or 18′
34a, 34b: greatest width between the corner of the active silicon layer 12 and the middle islands 18 or 18′
36, 36″: overhang of the active silicon layer 12
36′: overhang and flattening, respectively, at a 90° corner
38: reduced isolation trench width in the intersection area
40: diagonal width of the isolation trench
40′: gap width in a junction area
50: effective gap width at a 90° corner of a semiconductor region
100: intersection area
100′: junction area, alternative junction area 100″
110: 90° corner in a semiconductor region
150: first semiconductor device assembly and layout, respectively, for an isolation trench structure
150′: second semiconductor device assembly and layout, respectively, for an isolation trench structure

1. An isolation trench structure in a semiconductor device assembly, said isolation trench structure comprising:
isolation trenches forming one of an intersection area and a junction area; and
regions of semiconductor material defined by said isolation trenches and electrically insulated from each other,
wherein a spacing between two regions of semiconductor material, the spacing being separated by the isolation trenches, is reduced in the area.

2. The isolation trench structure of claim 1, wherein the width of the isolation trenches in the area is reduced by overhangs of the regions.

3. The isolation trench structure according to claim 1, wherein an isolated middle island of semiconductor material is provided as one of the semiconductor regions in the area.

4. The isolation trench structure according to claim 3, wherein the middle island has a quadratic shape and has substantially a 45° rotation with respect to a length direction of the trench edge of the isolation trenches with respect to linear edges or flanks of the middle island.

5. The isolation trench structure according to claim 3, wherein a gap width in the intersection area is reduced by the arrangement of the middle island such that the sum of two diagonal spacings approximately corresponds to the value of the isolation trench width outside the intersection area.

6. The isolation trench structure according to claim 1, wherein at least some of the regions are provided for operation at different potentials.

7. The isolation trench structure according to claim 1, wherein the regions of semiconductor material are formed on a buried insulating layer and the isolation trenches have a depth extending at least to the buried insulating layer prior to filling the isolation trenches.

8. An isolation trench structure comprising:
an intersection area of isolation trenches in a semiconductor device assembly, wherein regions for different potentials are electrically insulated from each other by the isolation trenches; and
a middle island situated in the center of the intersection of the isolation trenches, wherein the middle island includes the same material as the regions and is configured in shape, size and position such that the intersection area size is reduced to form a transition from one isolation trench to another isolation trench with a reduced width as compared to an isolation trench width.

9. The isolation trench structure according to claim 8, wherein the middle island has a quadratic shape and includes with respect to its linear edges or flanks a 45° rotation with respect to a length direction of the trench edges of at least one of the isolation trenches.

10. The isolation trench structure according to claim 8, wherein the regions are located in a semiconductor layer that is formed on a buried insulating layer.

11. The isolation trench structure according to claim 8, wherein additionally a junction area of isolation trenches with a middle island is provided.

12. The isolation trench structure according to claim 8, wherein a gap width formed in a transition within the intersection area is reduced by the arrangement of the middle island such that the sum of two diagonal spacings approximately corresponds to the width of the isolation trench outside the intersection area.

13. An isolation trench structure at least in an intersection area of isolation trenches of semiconductor device assemblies comprising:
semiconductor regions, wherein the semiconductor regions provided for different potentials are electrically insulated from each other by the isolation trenches; and
overhangs of the semiconductor regions, wherein a width of said isolation trenches in the intersection area is reduced by the overhangs of the semiconductor regions.

14. The isolation trench structure according to claim 13, wherein the semiconductor regions are formed on a buried insulating layer.

15. The isolation trench structure according to claim 13, wherein a junction area is provided, in which the width of the isolation trenches is reduced.

16. A layout pattern for forming an isolation trench structure in a semiconductor layer comprising:
isolation trenches;
a spacing between semiconductor regions; and
an intersection area of isolation trenches,
wherein the layout pattern is configured such that the spacing between semiconductor regions separated by the isolation trenches of the trench structure in the intersection area is less than a maximum trench width of each linear isolation trench section.
